(19) United States
(12) Patent Application Publication
(10) Pub. No.: US 2003/0231021 A1
(43) Pub. Date: Dec. 18, 2003

(54) Dynamic trimming technique for variations in oscillator parameters

(76) Inventors: Milad Alwardi, Allen, TX (US); J. Randall Cooper, Murphy, TX (US)

Correspondence Address: TEXAS INSTRUMENTS INCORPORATED, P O BOX 655474, M/S 3999, DALLAS, TX, 75265

(21) Appl. No.: 10/166,935

(22) Filed: Jun. 12, 2002

(51) Int. Cl. H03L 7/00

(52) U.S. Cl. 324/360; 324/100; 331/100

(57) ABSTRACT

Systems and methods are provided for adjusting the frequency of an oscillator to compensate for oscillator frequency variations resulting from changes in oscillator parameters. Measurement systems monitor one or more oscillator parameters. The capacitance of the oscillator is selectively adjusted based on the measurement of the one or more oscillator parameters. The change in capacitance compensates for changes in environmental and operating conditions that affect the oscillator parameters, such as temperature and applied voltage, and produces a relatively stable output frequency over a specified operating range.

### TECHNICAL FIELD

The present invention relates to electrical circuits and more particularly to methods for adjusting the frequency of an oscillator to compensate for changes in output frequency resulting from variations in oscillator parameters.

### BACKGROUND OF INVENTION

Oscillators are employed in many applications to provide timing signals for clocking or transmitting data, synchronizing signals, modulating and demodulating signals, counting application and many others. The accuracy of an oscillator depends on the accuracy of the frequency associated with the oscillator. Quartz crystal oscillators can provide highly accurate and stable frequency sources. However, quartz crystal oscillators are generally very expensive and require excessive power for use in certain applications. Consequently, simple oscillators are utilized, such as an oscillator comprised of a current source, capacitor, discharge circuit and delay circuits. However, the frequency of simpler oscillators is less accurate than the more expensive oscillators. Additionally, variations in environmental or operational parameters of an oscillator, such as temperature and applied voltages, affect the accuracy of the frequency of the oscillator. These variations are unacceptable in certain applications.

The proliferation of portable electronic devices for business and personal applications has significantly contributed to an increased use of rechargeable batteries. Laptop computers, notebook computers, cell phones, PDA devices, electronic games, and numerous other portable electronic devices continue to contribute to a more efficient and mobile society. Battery charging and monitoring devices have become increasingly important to aid in providing dependable extended periods of operation away from continuous AC or DC power sources. Battery monitors are intended to be extremely accurate devices for coulomb counting in battery powered devices. Oscillators are used to generate clock pulses that are used to increment and decrement counters used to accurately monitor and report the condition of a battery. In measuring the absolute value of a battery charge, one critical parameter is the frequency of an internal oscillator.

FIG. 1 illustrates a conventional simple oscillator circuit 10. The oscillator circuit 10 includes a current source 12 coupled to an applied voltage source V_{cc} and a primary capacitor 14. Over time, the current source 12 charges the primary capacitor 14. As the charge on the primary capacitor 14 accumulates, the voltage across the primary capacitor begins to increase. A comparator 16 compares the voltage across the primary capacitor 14 with a stable bandgap reference voltage, V_{REF}. When the voltage across the primary capacitor 14 exceeds the reference voltage V_{REF}, the comparator 16 transitions from a low state to a high state. A driver 18 is coupled to the output of the comparator 16. The driver 18 can be a series of multiple inverters to provide additional delay. The low to high transition at the output of the comparator 16 will create a similar transition at the output of the driver 18. A delay circuit 20 is coupled to the output of the driver 18. The output of the delay circuit 20 mirrors the input to the delay circuit (delay through the driver 18), but is delayed in time by a predetermined amount to provide complete discharge of the primary capacitor 14. The discharge switch 24 is coupled to delay circuit 20 and to the node 15 which couples the current source 12, the primary capacitor 14, and the comparator 16.

The low to high transition at the output of the delay circuit 20 turns the discharge switch 24 “ON”. When the discharge switch is turned “ON”, node 15 is effectively shorted to ground providing a discharge path for primary capacitor 14. As a result, the voltage across primary capacitor 14 begins to decrease. Eventually, the voltage across the primary capacitor 14 will drop below the reference voltage VREF, and the output of the comparator 16 will transition from high to low. This low signal will pass through driver 18 and the delay circuit 20 to the discharge switch 24. The low input to the discharge switch 24 will turn the switch “OFF” allowing the voltage on the primary capacitor 14 to begin to increase once again.

The result of the above sequence of events is repeated over and over again and results in the creation of a “saw tooth” shaped voltage signal that is output to a D-type flip-flop 26. The output of the driver 18 is coupled to the D type flip-flop 26 which converts the “saw tooth” signal to a square-wave clock signal. In this example, this function is accomplished by coupling the output of the driver 18 to the clock input of a D-type flip-flop 26 which has its D input tied to its inverted output. The Q output of D-type flip-flop 26 will be a square-wave frequency output which oscillates between high and low voltage levels.

The resulting frequency is a function of a number of variables including the current source 12, the size of the primary capacitor 14, the amount of delay through the comparator 16, the driver 18, the delay circuit 20, and the discharge switch 24. The accuracy of the frequency is affected by environmental or operational parameters of the oscillator such as temperature and the applied voltage V_{cc}. At a nominal temperature and applied voltage, a desired frequency may be obtained by appropriately selecting the current source 12 and the primary capacitor 14. As the temperature and applied voltage vary during normal use, the oscillator frequency is subject to change. In a battery monitoring application, this variation in frequency affects the accuracy of the information from the battery monitoring circuit that is dependent upon the accuracy of the frequency of the oscillator.

FIG. 2 illustrates the output frequency response of a conventional oscillator, such as that illustrated in FIG. 1, as a function of temperature and applied voltage. FIG. 2 consists of three curves, 30, 32, and 34. Curve 30 illustrates the oscillator frequency as a function of temperature for a given applied voltage V_{cc}=V1. Curve 32 illustrates the oscillator frequency as a function of temperature for a given applied voltage V_{cc}=V2 where V2 is less than V1. Curve 34 illustrates the oscillator frequency as a function of temperature for a given applied voltage V_{cc}=V3 where V3 is less than V2. All three curves illustrate that the oscillator output frequency will increase with an increase in temperature up to T0. Further increases in temperature above T0 result in a decrease in oscillator frequency. The output frequency variation as a function of temperature is primarily the result of changes in the V_{REF} as a function of temperature. A change in V_{REF} changes the amount of time necessary for the voltage across the primary capacitor 14 to exceed V_{REF} and thereby alters the oscillator frequency. Temperature variations result from both differing ambient conditions and from the internal heat generated during the operation of the device in which the oscillator resides.

The variation in oscillator frequency as a function of applied voltage is illustrated in FIG. 2 by comparing curves 30, 32 and 34. At any given temperature, an increase in voltage results in an increase in oscillator frequency. The change in frequency as a function of voltage is a fairly linear relationship. Simply stated, increasing applied voltages result in an increase in oscillator frequency. This fairly linear relationship is a result of an increase in charging current from the current source coupled to V_{cc}.

### SUMMARY OF INVENTION

The following presents a simplified summary of the invention in order to provide a basic understanding of some aspects of the invention. This summary is not an extensive overview of the invention. It is intended to neither identify key or critical elements of the invention nor delineate the scope of the invention. Its sole purpose is to present some concepts of the invention in a simplified form as a prelude to the more detailed description that is presented later.

The present invention relates to systems and methods for adjusting the frequency of an oscillator to compensate for frequency variations resulting from changes in oscillator parameters or variables (e.g., temperature, applied voltage) that affect the frequency of the oscillator. A dynamic trimming technique and trim circuit is provided to offset the frequency variations of an oscillator in response to changes in oscillator parameters. The output frequency of the oscillator is dynamically adjusted by adding or subtracting capacitors in parallel with a primary capacitor of the oscillator. The system comprises independent measurement systems, independent control systems and separate banks of trim capacitors which can be added or removed in parallel with the primary capacitor of the oscillator. The system offsets output frequency variations that naturally occur in response to changes in oscillator parameters.

In one aspect of the invention, a measurement system is provided that includes a temperature monitor. The output of the temperature monitoring is provided to a control system. The control system provides one or more control signals that switch in or switch out trim capacitors that are configured to be added or removed in parallel with the oscillators primary capacitor. Adding additional trim capacitors in parallel increases the total capacitance of the oscillator. Consequently, by switching in additional trim capacitors, the frequency of the oscillator will be decreased. Similarly, when a change in the temperature of the system results in a decrease in the frequency of the oscillator, the control system will switch out trim capacitors, resulting in an increase in oscillator frequency.

In another aspect of the invention, a measurement system is provided that measures or senses the applied voltage. A control system provides one or more control signals that switch in or switch out trim capacitors in response to the applied voltage level. The trim capacitors are configured to be added or removed in parallel to the primary capacitor of the oscillator. As operating conditions change and the applied voltage decreases, the control system will switch out trim capacitors to offset the decrease in oscillator frequency that results from a decrease in applied voltage. Similarly, an increase in applied voltage results in an increase in oscillator frequency which the system will offset by switching in additional trim capacitors.

The following description and the annexed drawings set forth certain illustrative aspects of the invention. These aspects are indicative, however, of but a few of the various ways in which the principles of the invention may be employed. Other advantages and novel features of the invention will become apparent from the following detailed description of the invention when considered in conjunction with the drawings.

### BRIEF DESCRIPTION OF THE DRAWINGS

FIG. 1 illustrates a schematic block diagram of a conventional oscillator.

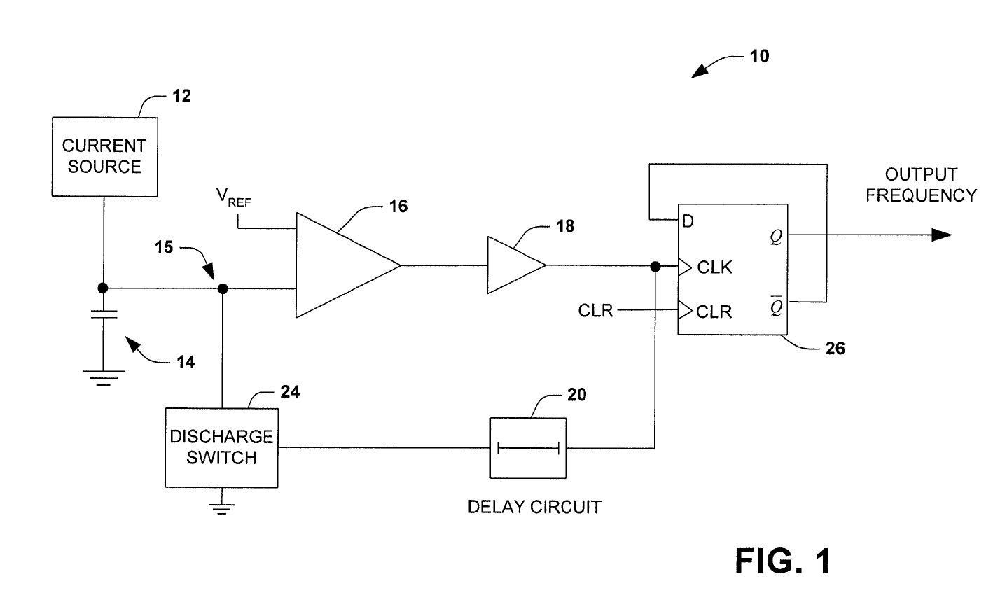

FIG. 2 illustrates a graph of frequency response as a function of temperature and applied voltage of the conventional oscillator.

FIG. 3 illustrates a block diagram of a dynamically trimmed oscillator system in accordance with an aspect of the present invention.

FIG. 4 is a schematic block diagram of an oscillator system in accordance with an aspect of the present invention.

FIG. 5 is a schematic block diagram of an alternate oscillator system in accordance with an aspect of the present invention.

FIG. 6 illustrates the application of an oscillator in a portable electronic device having a battery monitor in accordance with an aspect of the present invention.

FIG. 7 illustrates a flow diagram of a methodology for providing an oscillator system in accordance with an aspect of the present invention.

FIG. 8 illustrates a flow diagram of the operation of a dynamically trimmed oscillator system in accordance with an aspect of the present invention.

### DETAILED DESCRIPTION OF THE INVENTION

The present invention relates to systems and methods for adjusting the frequency of an oscillator to compensate for oscillator frequency variations resulting from changes in oscillator parameters (e.g., temperature, applied voltage). The present invention provides a system that dynamically trims an oscillator frequency to produce a relatively stable output frequency despite changes in oscillator parameters. A bank of trim capacitors and control circuitry provides for selectively adjusting the amount of capacitance that is added or removed in parallel with the primary capacitor of the oscillator. The change in capacitance compensates for changes in oscillator parameters, such as temperature and applied voltage. Measurement systems monitor the changes in oscillator parameters and are coupled to control systems that control the switching of a trim capacitor bank.

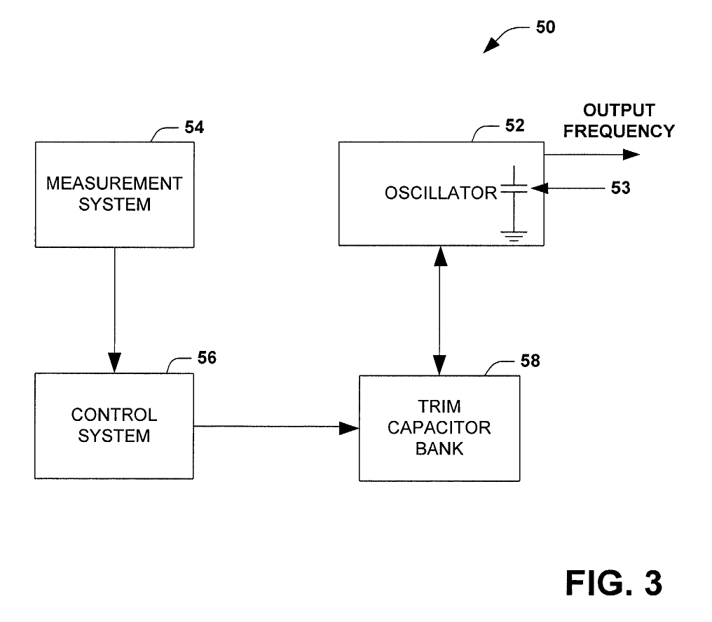

FIG. 3 illustrates a block diagram of a dynamically trimmed oscillator system 50 in accordance with an aspect of the present invention. The system 50 comprises an oscillator 52, a measurement system 54, a control system 56, and a trim capacitor bank 58. The oscillator 52 can include one or more capacitors that are charged and discharged to generate a signal utilized in the generation of the oscillator frequency. The one or more capacitors of the oscillator 52 are referred to herein as a primary capacitor 53. A trim capacitor bank 58 is coupled to the control system 56 and the oscillator 52. The trim capacitor bank 58 is comprised of one or more trim capacitors that are selectively added in parallel or removed from being in parallel with the primary capacitor 53. It is to be appreciated that the capacitors can be added or removed in series to provide a desired capacitance. In one aspect of the invention, the trim capacitors are between 10 and 100 fentofarads.

In the present example, the output frequency of the oscillator 52 is dynamically trimmed by selectively adding or removing capacitors from the trim capacitor bank 58 in parallel with the primary capacitor 53. The measurement system 54 is provided to measure an oscillator parameter that may vary during normal operating conditions and result in a change in the output frequency of the oscillator 52. These parameters include, for example, temperature and applied voltage. A control system 56 is coupled to the measurement system 54 and the trim capacitor bank 58. In response to the output of the measurement system 54, the control system 56 provides control lines that selectively add or remove capacitors from the trim capacitor bank 58 in parallel with the primary capacitor 53. It is to be appreciated that the measurement system 54 and the control system 56 can be integrated into a single system.

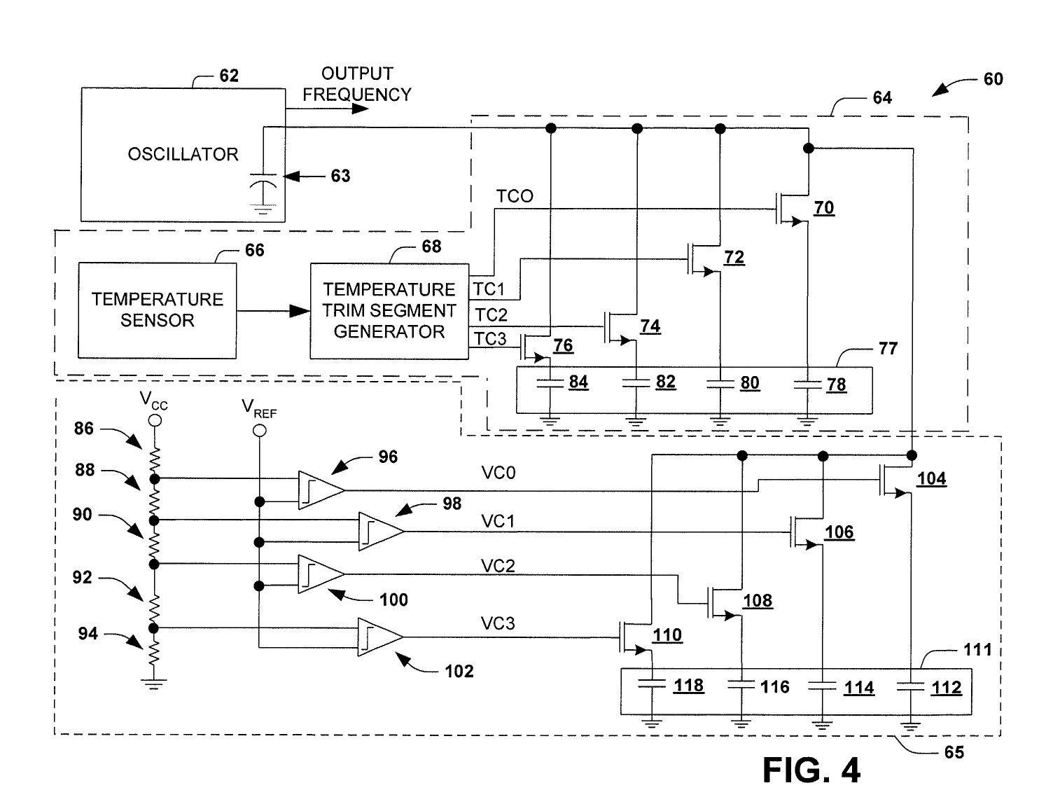

It is understood that one or more dynamic trimming circuits, each comprised of a measurement system and associated control system and capacitor bank, may be implemented in accordance with the present invention. For example, an oscillator system may implement a single dynamic trimming circuit to adjust output frequency for changes in operating or environmental temperature. Another oscillator system may implement a single dynamic trimming circuit to adjust output frequency for applied voltage variations. Still another oscillator system may implement independent dynamic trimming circuits to adjust output frequency for both changes in temperature and applied voltage variations. FIG. 4 is an illustration of such an implementation. Although the present invention is illustrated with respect to systems for dynamically trimming an oscillator in response to changes in temperature and voltage variations, other oscillator parameters that affect the operating frequency can be measured and utilized in dynamically trimming an oscillator.

FIG. 4 illustrates a dynamically trimmed oscillator system 60 in accordance with an aspect of the present invention. The system 60 alters the output frequency of an oscillator 62 for variations in both temperature and applied voltage. The oscillator 62 can be comprised of different components and one or more capacitors that are charged and discharged to generate a frequency. The one or more capacitors of the oscillator 62 are referred to as a primary capacitor 63 and can also be a single stand-alone capacitor. The system is further comprised of a temperature compensation circuit 64 and a voltage compensation circuit 65.

The temperature compensation circuit 64 is a measurement system comprised of a temperature sensor 66. A control system is provided comprised of temperature trim segment generator 68 and MOSFET switches 70,72,74, and 76. A trim capacitor bank 77 is provided for frequency adjustment of the oscillator 62 due to varying temperature and is comprised of capacitors 78, 80, 82 and 84. The temperature sensor 66 measures the temperature of the circuit and provides an output, based on the measured temperature, to the temperature trim segment generator 68. In one aspect of the invention, temperature resolution from the temperature sensor 66 is on the order of one degree Celsius. The temperature trim segment generator 68 has four temperature compensation output signals TC0, TC1, TC2 and TC3. Each temperature compensation output is coupled to the gate of an N-type MOSFET device that effectively adds or removes capacitors in parallel with the primary capacitor 63 of the oscillator 62.

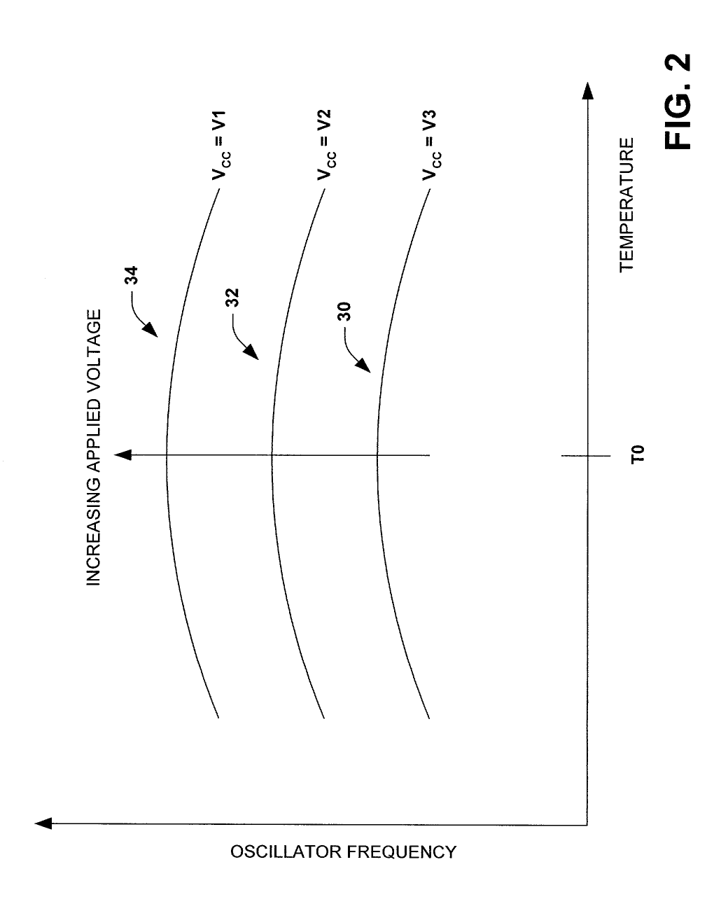

The nominal condition of each output signal is high such that the corresponding MOSFET device is turned “ON” and each associated trim capacitor is nominally in parallel with the primary capacitor 63. An associated temperature compensation output signal will become active for a specific temperature range. For example in one particular implementation, TC0 is active for temperatures (T) less than 0° C., TC2 is active for 0° C.<=T<20° C., TC3 is active for 40° C.<T<60° C., and TC4 is active for T>=60° C. No compensation output signal is active for the nominal temperature range of 20° C. to 40° C. This is because no correction is necessary at the nominal temperature, T0 (See FIG. 2). In the implementation of FIG. 4, T0=30° C. and no correction is necessary until the temperature varies by more than 10 degrees.

However, if the measured circuit temperature is outside of the temperature range of 20° C. to 40° C., then at least one of the temperature compensation output signals will be active low. For example, if the measured temperature is between 0° C. and 20° C., then a low signal on TC1 will turn off MOSFET device 70 which results in trim capacitor 78 being removed from being in parallel with primary capacitor 63. With trim capacitor 78 removed, the overall capacitance that a current source will charge is reduced resulting in an increase in frequency of the oscillator. TABLE I defines the state of the temperature compensation outputs for the above temperature conditions. It is to be appreciated that the number of trim segments can be increased or decreased as necessary to provide more accurate frequency resolution based on changes in temperature.

TABLE I

| Temperature | TC0 | TC1 | TC2 | TC3 |
|---|---|---|---|---|
| T < 0 | L | L | H | H |
| 0 <= T < 20 | H | L | H | H |
| 20 <= T < 40 | H | H | H | H |
| 40 <= T < 60 | H | H | L | H |
| 60 <= T | H | H | L | L |

Within the voltage compensation circuit 65, a measurement system is comprised of resistors that form a voltage divider. Resistors 86, 88, 90, 92 and 94 are coupled together in series, with one end of resistor 86 coupled to the applied voltage source V_{cc} and one end of resistor 94 coupled to ground, to form a voltage divider. As V_{cc} increases, the voltage at each stage of the voltage divider is also increased. A control system is comprised of comparators 96, 98, 100, and 102 and MOSFET switches 104, 106, 108, and 110. The comparators 96, 98, 100, and 102 compare a reference voltage V_{REF} to voltages created at the various stages of the voltage divider. When V_{cc} is low, the voltage at each stage of the voltage divider is less than the reference voltage. Therefore, none of the comparators detect a voltage higher than V_{REF} and each of the voltage compensation output signals VC0, VC1, VC2 and VC3 will be low. A trim capacitor bank 111 is provided for the frequency adjustment and is comprised of trim capacitors 112, 114, 116 and 118.

As V_{CC} is increased, the voltage at the node between resistor 86 and 88 will eventually exceed V_{REF} and comparator 96 will generate a high on voltage compensation output signal VC0. When VC0 goes high, switch 104 is turned “ON” effectively placing capacitor 112 in parallel with primary capacitor 63. A further increase in V_{CC} will result in the voltage at the node between resistor 88 and 90 exceeding V_{REF} and comparator 98 will generate a high on voltage compensation output signal VC1. When VC1 goes high, switch 106 is turned “ON” effectively placing capacitor 114 in parallel with the primary capacitor 63. As V_{CC} continues to increase, VC2 and VC3 will also become high, turning “ON” switches 108 and 110 resulting in capacitors 116 and 118 being added in parallel across primary capacitor 63. Each additional capacitor added in parallel across the primary capacitor 63 increases the capacitance of the oscillator 62 and serves to offset the frequency increase which would otherwise result from an increase in V_{CC}

It is to be appreciated that the number of applied voltage trim adjustments can be increased or decreased depending upon the needs of the particular system and range of the intended applied operating voltages. Additional stages of the voltage divider, comparators, MOSFET switches and trim capacitors can be added as necessary to achieve the desired results. It is also to be appreciated that a single control line can be enabled at one time to switch in a capacitor of a different value, or multiple control lines can be enabled to add capacitors from the switch banks together to reduces the number of necessary control lines. The voltage divider can also be replaced by an analog-to-digital converter (ADC) measurement system, which can already exist on board to measure other parameters. In this situation, a large number of voltage ranges can be generated similar to the temperature measurement system.

According to one aspect of the invention, the primary capacitor 63 is between about 1.0 picofarads and 1.5 picofarads and each trim capacitor 78, 80, 82, 84, 112, 114, 116, and 118 are of substantially equal value between about 20 and 1000 fentofarads. In accordance with another aspect of the invention, the primary capacitor 63 is between about 1.0 picofarads and 1.5 picofarads and trim capacitors 78, 80, 82, 84 are 40, 80, 160 and 240 fentofarads respectively and trim capacitors 112, 114, 116, and 118 are 40, 80, 160 and 240 fentofarads respectively.

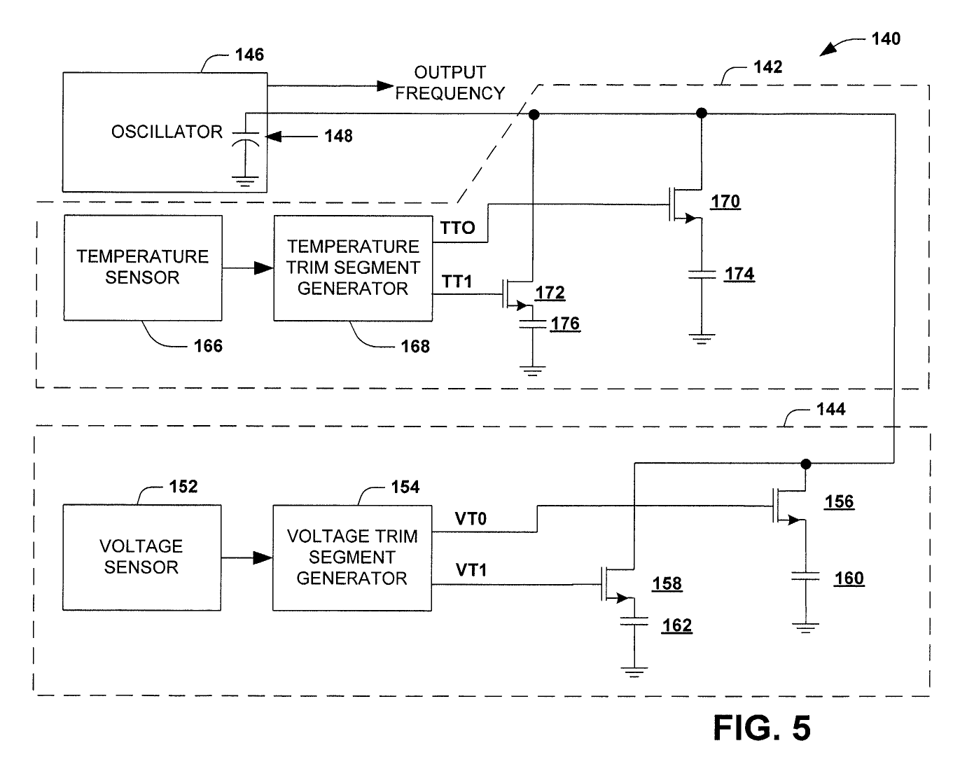

FIG. 5 illustrates an alternate system 140 in accordance with another aspect of the invention. In FIG. 5, alternative control circuits are utilized which allow for achieving similar results while requiring fewer switches and fewer capacitors, each capacitor in a trim bank being of a different value. The system 140 includes an oscillator 146 that contains a primary capacitor 148. The system 140 includes an applied voltage compensation system 144 and a temperature compensation system 142 that add and remove trim capacitors in parallel with the primary capacitor 148 of the oscillator 146. The applied voltage compensation system 144 includes a voltage sensor 152 and a voltage trim segment generator 154. The voltage sensor 152 monitors applied voltage V_{CC} and provides input to the voltage trim segment generator 154. The voltage trim segment generator 154 encodes the input from the voltage sensor on two voltage trim control signals VT0 and VT1. VT0 is coupled to the gate of MOSFET device 156. MOSFET device 156 is coupled to primary capacitor 148 and trim capacitor 160. Similarly, VT1 is coupled to the gate of MOSFET device 158 and MOSFET device 158 is coupled to primary capacitor 148 and trim capacitor 162.

In FIG. 5, each trim capacitor is about twice the value of a previous trim capacitor. For example, in one aspect the trim capacitor 160 is about 20 fentofarads and trim capacitor 162 is about 40 fentofarads. Control signals VT0 and VT1 are encoded so that when no trimming is required, both VT0 and VT1 are low. When the first increment of trim is required, VT0 is high and VT1 is low, adding 20 fentofarads of trim capacitance. When 40 fentofarads of trim capacitance are required, VT0 is low and VT1 is high and 60 fentofarads of trim capacitance is provided when both VT0 and VT1 are high. In this manner, four levels of trim are provided with just two capacitors. Trim capacitance is added or removed in increments of 20 fentofarads by encoding the control lines and using two trim capacitors, one twice the value of the other, instead of using three trim capacitors of 20 fentofarads each.

A similar approach is utilized in the temperature compensation system 142. The temperature compensation system 142 includes a temperature sensor 166 and a temperature trim segment generator 168. The temperature sensor 166 measures the circuit temperature and provides an output to the temperature trim segment generator 168. The temperature trim segment generator 168 encodes the input from the temperature sensor 166 on two temperature trim control signals, TT0 and TT1. TT0 is coupled to the gate of MOSFET device 170. MOSFET device 170 is coupled to the primary capacitor 148 and trim capacitor 174. Similarly, TT1 is coupled to the gate of MOSFET device 172 and MOSFET device 172 is coupled to the primary capacitor 148 and trim capacitor 176. In FIG. 5, each trim capacitor is a different value, each one being about twice the value of a previous trim capacitor. For example, in one aspect the trim capacitor 174 is about 20 fentofarads and trim capacitor 176 is about 40 fentofarads.

For the temperature compensation system 142, the control lines are encoded so that both TT0 and TT1 are high at the temperature where the oscillator output frequency is at its maximum frequency (see T0 of FIG. 2). From this point, either an increase or decrease in temperature will result in a decrease in the output frequency of the oscillator 146. In order to offset the decrease in frequency, trim capacitors are removed from being in parallel with primary capacitor 148. Control signals TT0 and TT1 are encoded so that when no trimming is required (e.g., T0), both TT0 and TT1 are high, which turns “ON” switches 170 and 172 and places both trim capacitors 174 and 176 in parallel with primary capacitor 148.

When the first increment of trim is required, TT0 is low and TT1 is high, removing the 20 fentofarads of trim capacitor 174 from being in parallel with primary capacitor 148. When 40 fentofarads of trim are required to be removed, TT0 is high and TT1 is low, removing trim capacitor 176, but leaving trim capacitor 174 in parallel with primary capacitor 148. When both TT0 and TT1 are low, turning “OFF” both switch 170 and 172, thereby removing trim capacitors 174 and 176 and removing 60 fentofarads of trim capacitance. In this manner, four levels of trim are provided with just two capacitors. Trim capacitance is added or removed in increments of 20 fentofarads by encoding the control lines and using two trim capacitors, one being 20 fentofarads and the other being 40 fentofarads instead of three trim capacitors each being 20 fentofarads.

Since for temperature compensation, trim capacitance must be removed for either an increase or a decrease in temperature, the control lines are encoded to provide removal of trim capacitors for both increases or decreases from T0 in temperature. Furthermore, since the frequency response of the oscillator 146 is symmetrical around T0 for changes in temperature, the same trim capacitors are removed for either an increase or decrease in temperature. For example, TT0 goes low when the temperature either increases or decreases from T0 by an amount approximately equal to 10° C.

By encoding the control lines, providing a bank of trim capacitors which double in value, and by taking advantage of the symmetrical frequency response around TO, the temperature compensation circuit is implemented with fewer trim capacitors. Alternatively, a higher level of temperature compensation fidelity (i.e. more temperature ranges) can be achieved for a given number of capacitors.

A range of temperatures or voltages for which a different level of trim is required is referred to as a compensation band. If each compensation band adds a single capacitor of equal value, then it will require 16 trim capacitors to implement 16 compensation bands. If, however, the trim control lines are encoded and trim capacitors double in value, then 16 compensation bands can be implemented with just 4 trim capacitors. In the case of temperature compensation, which is symmetrical about a temperature T0, 16 compensation bands can be implemented with just three trim capacitors, each doubling in value.

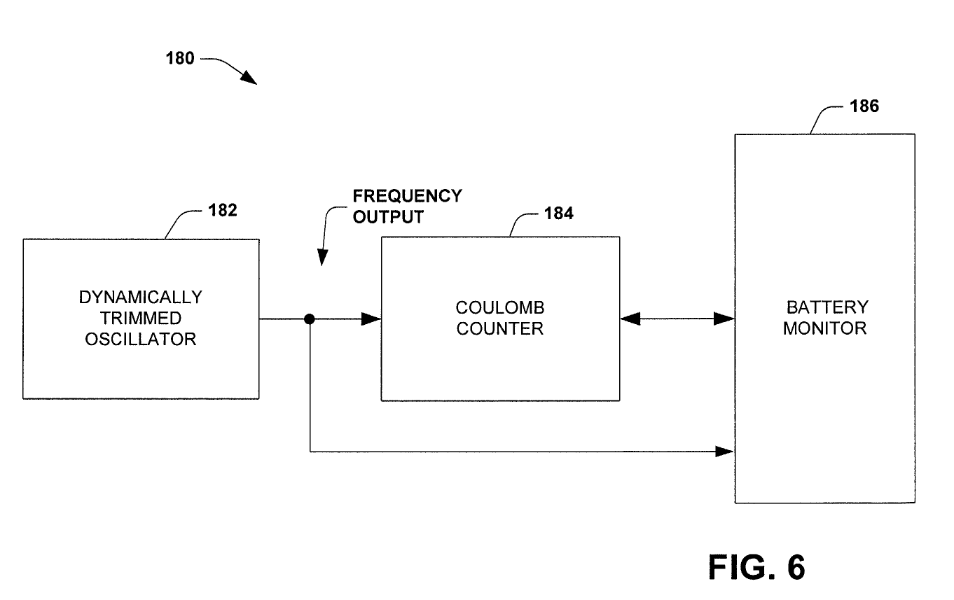

FIG. 6 illustrates a portable electronic device 180 utilizing a dynamically trimmed oscillator 182 in accordance with an aspect of the present invention. In this type of application, the stability of the frequency output of the oscillator impacts the accuracy of a battery monitor 186. The dynamically trimmed oscillator 182 comprises the oscillator system of FIG. 5, dynamically trimmed for both the temperature and applied voltage variations. As such, the frequency output is much more stable and accurate than a conventional oscillator. The frequency output of the dynamically trimmed oscillator 182 is coupled to a coulomb counter 184 and other registers and counters within the battery monitor 186. Since the frequency output of the dynamically trimmed oscillator is adjusted to compensate for variation in temperature and applied voltage, the accuracy and usefulness of the battery monitor 186 is significantly increased.

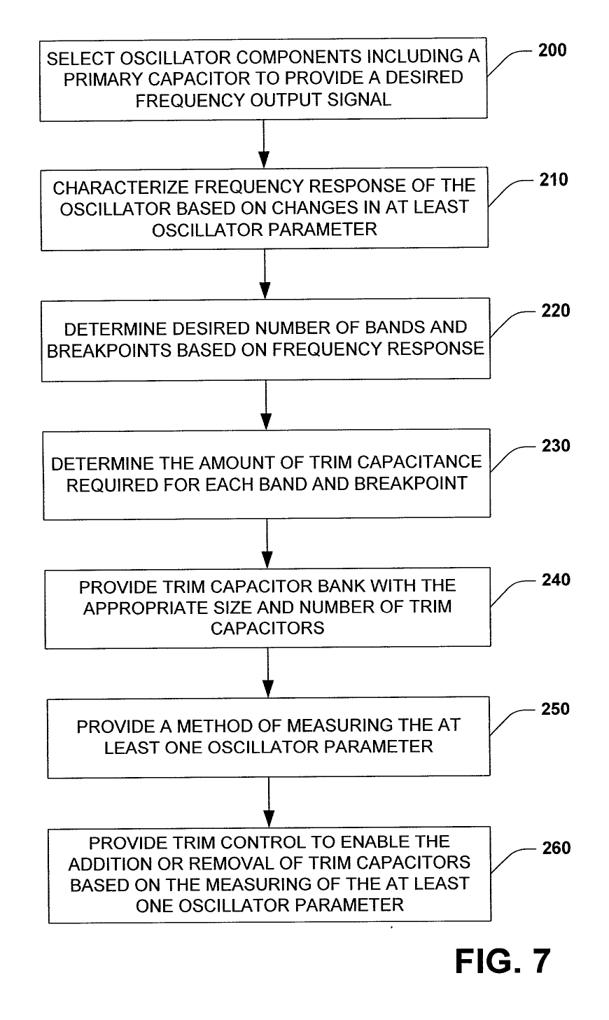

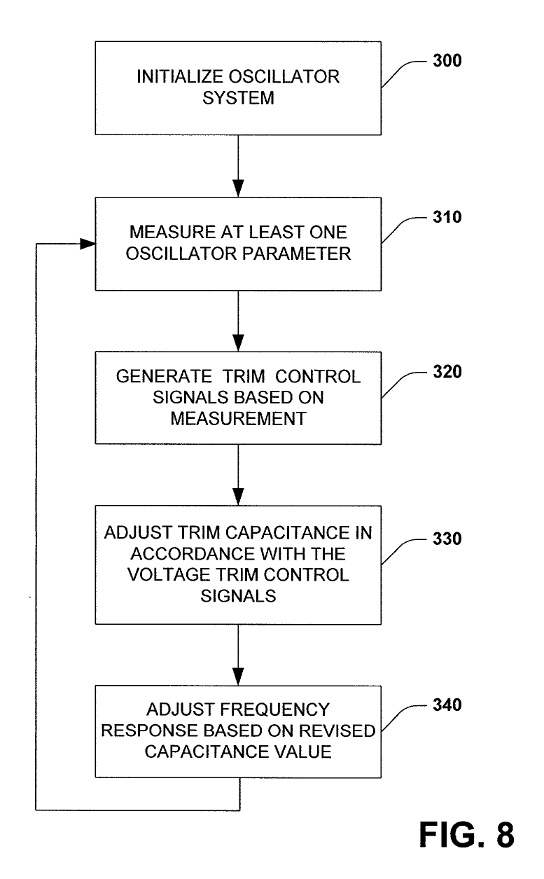

In view of the foregoing structural and functional features described above, methodologies in accordance with various aspects of the present invention will be better appreciated with reference to FIGS. 7-8. While, for purposes of simplicity of explanation, the methodologies of FIGS. 7-8 are shown and described as primarily executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect the present invention.

FIG. 7 illustrates one particular methodology for providing an oscillator trimming system in accordance with the present invention. The methodology begins at 200 where selection of oscillator components is performed, including a primary capacitor, to provide a desired frequency output signal. At 210, the frequency response of the oscillator is determined based on changes of at least one oscillator parameter (e.g., temperature, applied voltage). For example, typical oscillators have a temperature T0 at which the frequency is a maximum and the output frequency will decrease with either a rise or fall in temperature. Information can be gathered on the output frequency as function of temperature over the desired operating temperature range. Typical oscillators have a linear relationship between the applied voltage and the frequency output such that an increase in applied voltage results in an increased output frequency. Information can be gathered on the output frequency as function of applied voltage over the desired operating range.

The methodology then proceeds to 220 where the desired number of bands and breakpoints is determined based on the frequency response. A breakpoint is where one band ends and another band begins. At 230, the amount of trim capacitance required to maintain a substantially constant frequency output at each band and breakpoint is determined. At 240, a trim capacitor bank is provided with the appropriate size and number of trim capacitors. The capacitor bank is designed to provide a number of trim capacitors wherein each trim capacitor is approximately twice the capacitance of the previous trim capacitor and the capacitor bank is designed to use the trim capacitors both in isolation from each other and in combination with each other. It is understood that the capacitor bank can be designed in a number of other fashions. For example, the capacitor bank can consist of a number of identically sized trim capacitors that are used in additive fashion, or can consist of a number of capacitors each of different sizes that are used in isolation. A method of measuring the at least one oscillator parameter is provided at 250. At 260, trim control is provided to enable the addition or removal of trim capacitors based on the measuring of the at least one oscillator parameter.

FIG. 8 illustrates one particular methodology for operation of an oscillator system having an oscillator with a primary capacitor that provides a frequency output signal in accordance with an aspect of the present invention. The method begins at 300 where the system is initialized when power is turned on to the oscillator system causing the oscillator to begin providing a frequency output signal. The methodology then proceeds to 310. At 310, at least one oscillator parameter (e.g., temperature, applied voltage) that affects the frequency of the frequency output signal of the oscillator is measured. At 320, trim control signals are generated in response to the measurement of the at least one oscillator parameter. At 330, a trim capacitance is adjusted in accordance with the state of the voltage trim control signals. The voltage trim control signals add or remove voltage trim capacitors in parallel with the primary capacitor of an oscillator of the oscillator system. Then at 340, the frequency response of the frequency output signal of the oscillator is adjusted based on the revised capacitance value. The methodology then returns to 310.

What has been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. An oscillator system comprising:
an oscillator that provides a frequency output signal;
a measurement system operable to measure at least one oscillator parameter that affects the frequency of the frequency output signal; and
a capacitor bank having at least one trim capacitor coupleable to the oscillator, the at least one trim capacitor being coupled to the oscillator to adjust the frequency of the output signal when the measurement of the at least one oscillator parameter indicates an effect on the frequency of the output signal.

2. The system of claim 1, the at least one oscillator parameter being temperature.

3. The system of claim 1, the at least one oscillator parameter being applied voltage.

4. The system of claim 1, the oscillator comprising a primary capacitor that at least in part determines the frequency of the frequency output signal.

5. The system of claim 4, the oscillator further comprising a current source coupled to the primary capacitor and a capacitor discharge switch coupled to the primary capacitor.

6. The system of claim 4, further comprising a control system operable to switch the at least one trim capacitor in and out in parallel with the primary capacitor based at least in part on the output of the measurement system.

7. The system of claim 1, the capacitor bank comprising a plurality of trim capacitors that are switched in and out one at a time.

8. The system of claim 1, the capacitor bank comprising a plurality of trim capacitors that are switched in and out in a sequence.

9. The system of claim 1, the capacitor bank comprises a plurality of trim capacitors of substantially equal values.

10. The system of claim 1, the capacitor bank comprises a plurality of trim capacitors of differing values.

11. The system of claim 8, such that each successive capacitor is twice the capacitance of the previous capacitor.

12. A battery monitor comprising the oscillator of claim 1.

13. A system for adjusting the frequency of an oscillator that provides a frequency output signal having a frequency that is based at least in part by a primary capacitor value, the system comprising:
a temperature measurement system operable to measure temperature of the oscillator;
an applied voltage measurement system operable to measure an applied voltage to the oscillator; and
a capacitor bank having a plurality of capacitors coupleable to the primary capacitor to adjust the frequency of the output signal based on the measurement of at least one of the temperature and the applied voltage that indicates an effect on the frequency of the output signal.

14. The system of claim 13, the temperature measurement system being a temperature sensor.

15. The system of claim 13, the applied voltage measurement system being one of a voltage divider device and an analog-to-digital converter.

16. The system of claim 13, further comprising a temperature control system that receives signals from the temperature measurement system and switches trim capacitors in and out of a parallel relationship with the primary capacitor based on the received signals.

17. The system of claim 16, the temperature control system comprising a temperature trim segment generator and a plurality of switches coupled to a plurality of trim capacitors.

18. The system of claim 16, the temperature control system switches trim capacitors in parallel for a first set of temperature bands and switches out trim capacitors in parallel for a second set of temperature bands.

19. The system of claim 13, further comprising an applied voltage control system that receives signals from the applied voltage measurement system and switches trim capacitors in and out of a parallel relationship with the primary capacitor based on the received signals.

20. The system of claim 18, the applied voltage control system comprising a plurality of comparators coupled to a reference voltage and the voltage measurement system, and a plurality of switches controlled by the plurality of comparators and coupled to a plurality of trim capacitors.

21. The system of claim 19, the applied voltage control system switches trim capacitors in parallel as the applied voltage decreases.

22. A method of providing an oscillator system comprising;
selecting components of an oscillator including a primary capacitor to provide a desired frequency output signal;
characterizing a frequency response to changes in at least one oscillator parameter that affects the frequency of the frequency output signal;
determining the number of desired bands and the breakpoints based on the frequency response;
determining a trim capacitance required for each band;
providing a bank of trim capacitors of appropriate size and number corresponding to the band;
providing a method to measure the at least one oscillator parameter; and
providing a control system to enable the addition and removal of trim capacitors based on the measurement of the at least one oscillator parameter.

23. The method of claim 22, the at least one oscillator parameter being temperature.

24. The method of claim 22, the at least one oscillator parameter being applied voltage.

25. A method for adjusting the frequency of an oscillator that provides a frequency output signal having a frequency that is based at least in part by a primary capacitor value, the method comprising:
initializing the oscillator system causing the oscillator to provide a frequency output signal;
measuring at least one oscillator parameter that affects the frequency of the frequency output signal; and
adjusting the capacitance of the primary capacitor value based on the measuring of the at least one oscillator parameter.

26. The method of claim 25, the measuring at least one oscillator parameter that affects the frequency of the frequency output signal comprising measuring at least one of temperature and applied voltage.

27. The method of claim 25, the adjusting the capacitance of the primary capacitor value based on the measuring of the at least one oscillator parameter comprising switching trimming capacitors in and out of a parallel relationship with the primary capacitor.

28. A system for adjusting a frequency output signal comprising;
means for providing a frequency output signal;
means for measuring an oscillator parameter that affects the frequency of the frequency output signal; and
means for dynamically adjusting the frequency of the frequency output signal based on a measurement of the oscillator parameter.

29. The system of claim 28, the means for dynamically adjusting the frequency of the frequency output signal comprising trimming a capacitance associated with the means for providing a frequency output signal, the capacitance determines at least in part the frequency of the frequency output signal.

30. The system of claim 29, the trimming a capacitance comprises switching at least one trim capacitor in and out of a parallel relationship with a primary capacitor, the primary capacitor determines at least in part the frequency of the frequency output signal.

31. A portable electronic device comprising the system of claim 28.
